(19) United States
(12) Patent Application Publication
(10) Pub. No.: US 2021/0331201 A1
(43) Pub. Date: Oct. 28, 2021

(54) PAINT MASK ASSEMBLY AND METHODS OF USE

(71) Applicant: AmpThink, LLC, Garland, TX (US)

(72) Inventor: William C. ANDERSON, III, Dallas, TX (US)

(21) Appl. No.: 16/858,020

(22) Filed: Apr. 24, 2020

(51) Int. Cl. B05D 1/32

(52) U.S. Cl. CPC B05D 1/322

(57) ABSTRACT

Paint mask assemblies are described herein in various embodiments. A paint mask assembly includes a window portion having a removable mask affixed thereto. The paint mask assembly can be affixed over a mark on a surface so that the mark is visible through the window portion of the paint mask assembly. When the paint mask assembly is painted, the paint is applied over the removable mask, but the window portion remains unpainted. When the removable mask is removed, the mark remains visible through the window portion of the paint mask assembly.

### BACKGROUND

Sometimes, a manufacturer or processor of a product imprints a mark, or stamp, on a product to identify the source of the product, a particular property of the product, a certification of the product, etc. Subsequently, if such a product is painted, the mark is often painted over and the information provided by the mark is gone. Although a painter may be able to mask the mark prior to painting the product, it is not uncommon for a painter not to know that a mark should be preserved and remain unpainted. In some instances, a product that a painter uses to mask such a mark (e.g. masking tape), may remove a mark that is merely printed on a product, thus preventing the mark from being masked by typical methods. In other cases, masking tape applied over a mark may become detached prior to the product being painted. In any case, such masking and painting leaves an undesirable aesthetic.

### SUMMARY

Several embodiments of a paint mask assembly are described herein. The paint mask assembly includes a frame portion and a window portion. The frame portion can be affixed over a mark on a surface so that the mark is visible through the window portion of the paint mask assembly. The paint mask assembly also includes a removable mask applied to the window portion so when the paint mask assembly is painted, the paint is applied over the removable mask, but the window portion remains unpainted. When the removable mask is removed, the mark remains visible through the window portion of the paint mask assembly.

### BRIEF DESCRIPTION OF THE DRAWINGS

A particular description of the principles briefly described above will be rendered by reference to specific embodiments thereof, which are illustrated in the appended drawings. Understanding that these drawings depict only certain exemplary embodiments of the disclosure and are not therefore to be considered to limit its scope, the principles herein are described and explained with additional specificity and detail through the use of the accompanying drawings.

FIG. 1 depicts a prior art sheet of wood stamped with certification marks.

FIG. 2 depicts an example paint mask assembly as described herein.

FIG. 3 depicts components of an example paint mask assembly and attachment means as described herein.

FIG. 4 depicts an alternate embodiment of components of an example paint mask assembly as described herein.

FIG. 5 depicts an embodiment of an example paint mask assembly having alternate attachment means.

FIGS. 6a-6c depict a method of using an example paint mask assembly as described herein.

### DETAILED DESCRIPTION

The following description relates to several embodiments of a paint mask assembly that can be used to protect an important mark on a product, such as a trademark identifying a source of the product, a certification mark identifying that the product conforms to certain standards, a mark that identifies a property of the product, and the like. Many products are provided to consumers with such marks. But some of those products are likely to be painted by an end user, thus covering the mark and eliminating the information that the mark was meant to convey. It is common that painters who paint such products are aware that the mark needs to be preserved, and they use typical methods to mask the mark prior to painting so that the mark is not permanently covered. However, there are circumstances that can prevent successful masking of the mark in this manner.

For example, if the mark is printed on the product and is masked with masking tape for painting, the mark may be damaged or removed when the masking tape is removed. This is especially true if a surface to which the mark is applied is not completely solid or includes a loose component that may become detached from the surface, such is the case on a plywood surface. In other cases, a tradesman knowledgeable of the importance of preserving a mark may install a product, but painting the product is done by a different tradesman who does not know to properly mask the mark for preservation. The techniques described herein prevent these types of failures from occurring so that the mark, and the intent of the mark, is preserved.

For clarity, the present discussion focuses on a particular case in which the present techniques may be employed, to-wit: using a paint mask assembly to preserve a fire certification mark on a plywood sheet that has been treated with a fire retardant material and is installed in a structure and painted. However, it will be apparent to those skilled in the art that the techniques presented herein may be applied in any situation where permanent preservation of a visible mark on a product is desired.

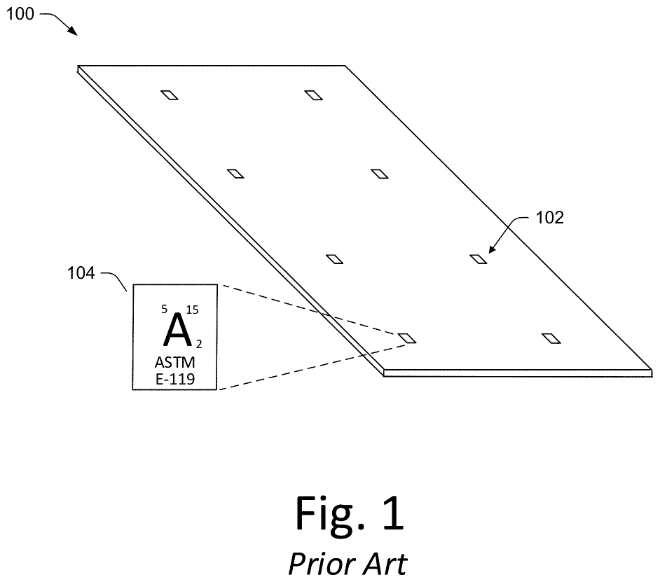

FIG. 1 is a depiction of a prior art sheet of plywood 100 on which is printed a number of fire stamps 102 that indicate that the plywood 100 has been tested according to particular fire standards and rated accordingly. The fire stamps 102 are comprised of ink, and they are typically printed on the plywood 100 using a roller printing method. A fire resistance rating mark 104 is shown in each fire stamp 102. The fire resistance rating mark 104 indicates the testing standards used in the certification and the rating of the plywood 100 as a result of the testing. Fire resistance is the ability of an assembly constructed in a laboratory to contain a fire in a carefully controlled test setting for a specified period of time. ASTM E-119 is the test standard for determining the fire resistance rating of partitions, floor-ceiling assemblies, roof-ceiling assemblies, beams, and columns. Fire resistance ratings represent results of tests on assemblies made up of specific materials in a specific configuration. When selecting construction designs to meet certain fire resistance requirements, caution must be used to ensure that each component of the assembly is the one specified in the test.

Some construction plans specify that only building materials that are certified to a particular fire resistance ratings be used. For example, such a requirement is common for rooms that may house heat-generating equipment, such as computer rooms, telecom rooms, utility closets, etc. As a result, inspectors must be able to confirm that proper materials were used upon completion of an installation. The present example contemplates fire rated plywood installed to create walls in a room. In most such cases, the walls are painted as part of the construction, but they are painted before they are inspected. If a fire stamp 102 is painted over, the inspector won't be able to certify that the proper materials were used and the inspector will fail the room. Therefore, it is important that visibility of the fire stamp is preserved for post-painting inspection.

One way that is currently in use to solve this problem is for a fire-rated plywood provider to pre-paint the wood and add a tag mark indicating that the wood that was painted conforms to certain fire ratings. But this has its problems. For one, such plywood has to be painted at a particular location of a facility that performs this service. That facility may be a distance from where the plywood will be installed, thus requiring significant shipping costs to get the certified plywood to the construction site. Another problem is that this method requires painting of certain pre-cut sizes of plywood. A tradesman who installs such plywood often needs to cut the plywood to fit the site, and this means that unpainted surfaces can be revealed that must be painted on site to avoid an undesirable aesthetic. Further, the plywood may be cut on site to fit the needs of the particular location, but the tag is applied off-site. The tag may end up in a location where it would be visible, such as behind equipment installed on or near a wall. The techniques described herein allow construction managers to buy fire-rated plywood nearer to the construction site and to paint the plywood upon completion of the installation, thus avoiding shipping costs and aesthetic issues. Furthermore, an installer can install boards as he sees fit and locate the tag where it is easily accessible to an inspector.

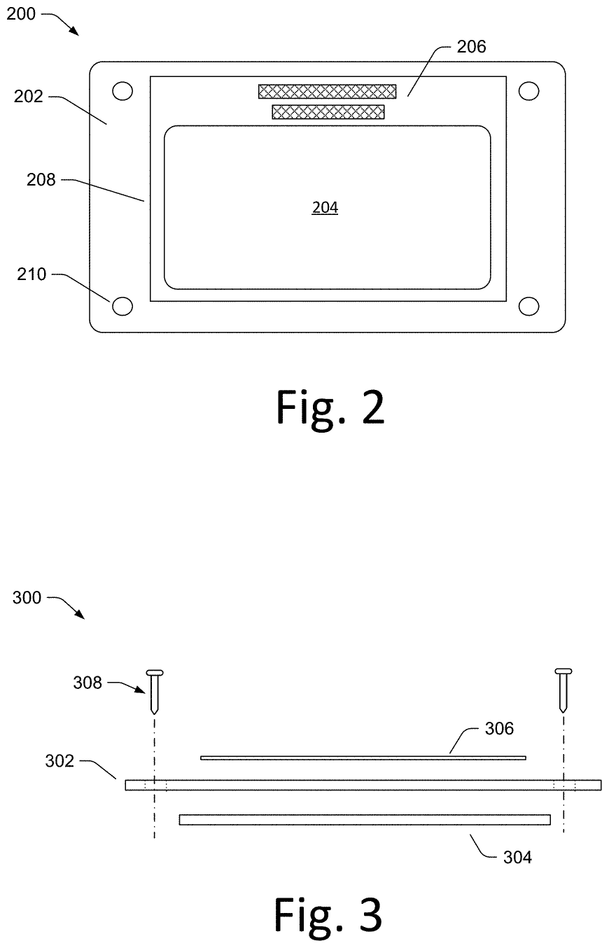

FIG. 2 depicts an example paint mask assembly 200 in accordance with the present description. The paint mask assembly 200 includes a frame 202 surrounding a window 204. In one or more alternate embodiments, the frame 202 and window 204 may be incorporated into a unified piece, such as a the case if the frame 202 and window 204 are comprised of a single piece of plastic, plexiglass, or the like. The frame 202 provides structural support for the window 204, which is transparent so that a mark placed under the window 204 is visible. The frame 202 includes a branding area 206, where a merchant or tradesman may apply a trademark or other information identifying a source of the paint mask assembly 200 or information related to some other entity, such as a business that installed the product on which the paint mask assembly 200 is attached, business contact information for a business that provides support for equipment to be used in a room where a product with the paint mask assembly 200 has been installed, etc.

The paint mask assembly 200 also includes a removable mask 208 that is applied over the window 204 to protect the window 204 from being painted when a product to which the paint mask assembly 200 is attached is painted. The removable mask 208 may also be transparent to aid an installer in locating the paint mask assembly 200 over a mark to be protected, but the removable mask 208 may also be semi-transparent or opaque. The removable mask 208 covers at least a portion of the window 204 sufficient to allow a mark to be visible through the window 204 after paint is applied and the removable mask 208 is removed. In the present example, the removable mask 208 covers the entire window 204 and the branding area 206 in order to preserve any branding that may be present. In at least one alternate embodiment, the removable mask 208 covers the entire frame 202 and window 204.

The paint mask assembly 200 also includes attachment means 210 that provide a way for the paint mask assembly 200 to be attached to a surface of a product containing a mark to be preserved. In the present example, the attachment means 210 include nail holes through which brads or nails can be inserted to secure the paint mask assembly 200 to an underlying surface. Those skilled in the art will recognize that any known method may be used to attach the paint mask assembly 200 to an underlying surface, such as an adhesive applied to a rear of the frame 202, cleats formed in the frame 202, and the like. It is noted that in at least one alternate embodiment, attachment means are not included. In such case, an installer provides attachment means, such as inserting staples through the frame 202 and into an underlying surface to secure the paint mask assembly 202 to the underlying surface.

FIG. 3 depicts an example paint mask assembly 300 that shows a particular arrangement of components. The paint mask assembly 300 includes a frame 302, a window 304, and a removable mask 306. The window 304 of the paint mask assembly 300 is formed of a transparent or semi-transparent materials such as plastic, glass, vinyl, or any polymer material that suits the purposes described herein. Nails 308 inserted through the frame 302 are used to attach the paint mask assembly 300 to an underlying surface.

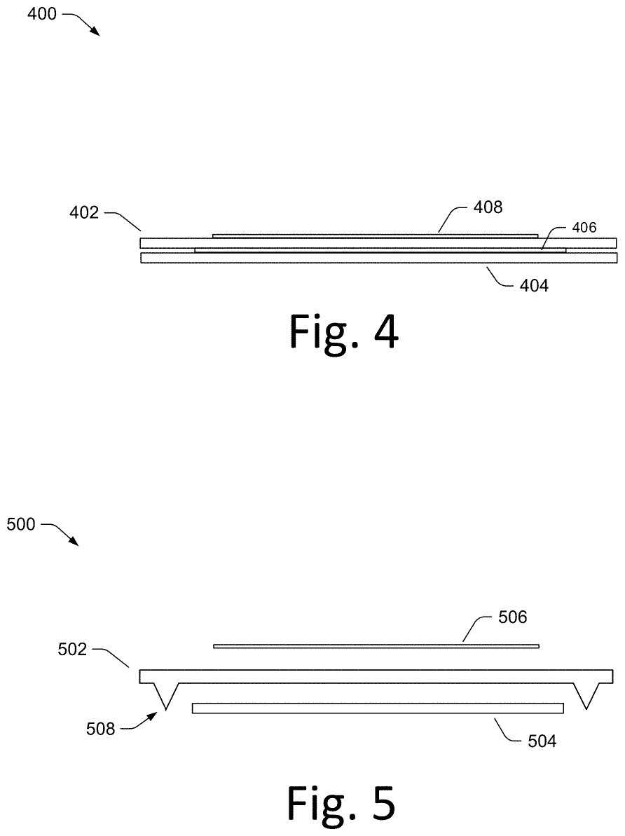

FIG. 4 depicts an alternate embodiment of an example paint mask assembly 400. The example paint mask assembly 400 includes a front frame 402 and a rear frame 404 that sandwich a window 406 between them. The front frame 402 and the rear frame 404 may be made of metal, plastic, vinyl, polymer, wood, pressed paper, or any other material suitable for the purposes described herein. The window 406 may be made of any transparent or semi-transparent material suitable for the purposes described herein including, but not limited to, plastic film, plastic sheet, plexiglass, glass, etc. The example paint mask assembly 400 also includes a removable mask 408 removably attached to the window 406, typically by an adhesive. The removable mask 408 covers at least a portion of the window 406 sufficient to allow a mark (not shown) to be seen through the window 406 when the paint mask assembly 400 is placed over the mark. The removable mask 408 may cover the entire surface of the front frame 402 and window 406, a portion thereof, or only the window 406 or a portion thereof.

FIG. 5 depicts an example paint mask assembly 500 in accordance with the present description. The paint mask assembly 500 includes a frame 502, a window 504, and a removable mask 506 releasably attached to the frame 502 and/or the window 504. The frame further includes a plurality of cleats 508 that can be used to attach the paint mask assembly 500 to the surface of a product (not shown) into which the cleats 508 can be inserted. In the present example, the frame 502 and cleats 508 are made of metal, and the paint mask assembly 500 may be attached to an underlying surface by applying a force (e.g. hammer) to the frame 502 to drive the cleats 508 into the underlying surface, which is commonly made of wood.

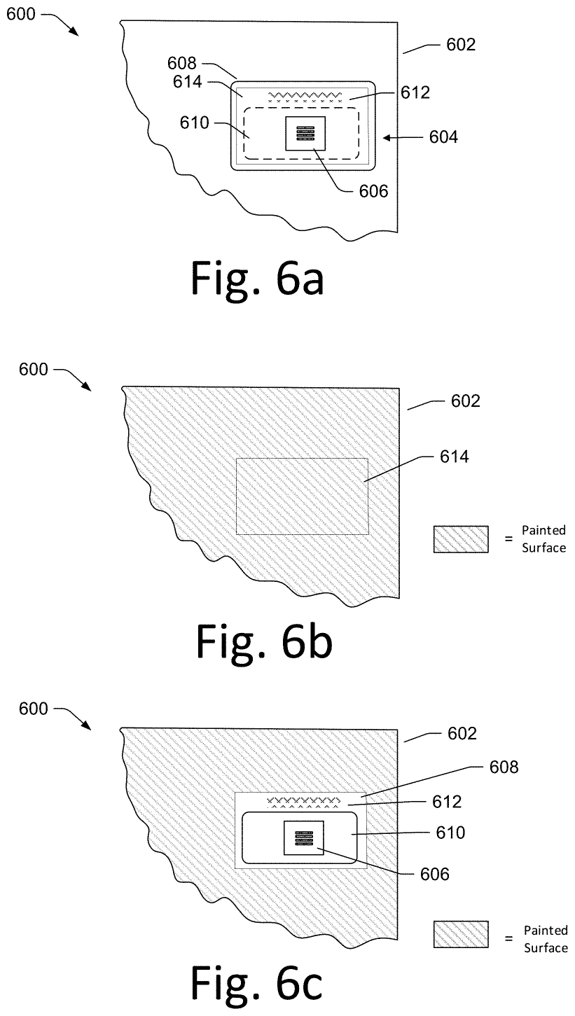

FIGS. 6a-6c depict an example method of use of a paint mask assembly as described herein. Each figure shows a fire rated board assembly 600 in different stages of the process. FIG. 6a shows an unpainted piece of plywood 602 that has a fire stamp 604 printed on it. A paint mask assembly 606 is shown attached to the plywood 602. The paint mask assembly 606 includes a frame 608 that surrounds a window 610, the frame 608 having a brand 612 printed thereon. A removable mask 614 is removably attached to the frame 606 and the window 610 of the paint mask assembly 606. The removable mask may be made of any suitable material including, but not limited to, plastic, vinyl, polymer, paper, etc. In the present embodiment, the removable mask 614 is sufficiently transparent for the fire stamp 604 to be visible through the window 610 and the removable mask 614. The paint mask assembly 606 is attached to the plywood 602 by any suitable means known in the art.

FIG. 6b depicts the fire rated board assembly 600 after it has been painted. All exposed surfaces, including the plywood 602 and the removable mask 614, have been covered by paint or some other opaque substance. It is noted that although the removable mask 614 has been painted, an outline of the removable mask 614 can be seen so that the removable mask 614 can be removed at the appropriate time.

FIG. 6c depicts the fire rated board assembly 600 after the removable mask 614 has been removed. Although the plywood 602 is painted, when the removable mask 614 is removed, then the area and components under the removable mask 614 are visible and unpainted. In this particular example, removal of the removable mask 614 exposes the frame 608, the window 610, and the brand 612. Furthermore, the fire stamp 604 is visible through the window 610. Thus, the plywood 602 is painted according to a specified finish, and the fire rating of the plywood can be confirmed.

### CONCLUSION

While the invention is described with respect to certain embodiments and/or generally associated methods, alterations and permutations of these embodiments and application to any application, a person having ordinary skill in the art will recognize other applications in which the presently described paint mask assembly may be used. Accordingly, the above description of example embodiments does not define or constrain this disclosure. Other changes, substitutions, and alterations are also possible without departing from the spirit and scope of this disclosure, as defined by the following claims.

1. A paint mask assembly, comprising:
a frame that is attachable to a surface over a mark on the surface;
a window within the frame, the mark on the surface being visible through the window when the frame is attached to the surface over the mark;
a removable mask removably attached to and covering at least a portion of the window; and
wherein when paint is applied to the paint mask assembly, the removable mask prevents paint from being applied to the window so that the mark on the surface remains visible through the window when the removable mask is removed from the window.

2. The paint mask assembly as recited in claim 1, further comprising attachment means to attach the paint mask assembly to the surface.

3. The paint mask assembly as recited in claim 2, wherein the attachment means further comprises holes through which nails can be driven to attached the paint mask assembly to the surface.

4. The paint mask assembly as recited in claim 2, wherein the attachment means further comprises adhesive applied to a surface of the frame that comes into contact with the surface when the paint mask assembly is attached to the surface.

5. The paint mask assembly as recited in claim 2, wherein the attachment means further comprises cleats integrated into the frame.

6. The paint mask assembly as recited in claim 1, wherein the removable mask also covers at least a portion of the frame.

7. The paint mask assembly as recited in claim 1, wherein the frame further includes a branding area that may include written information.

8. The paint mask assembly as recited in claim 7, wherein the removable mask is removable attached to and covers at least a portion of the window and the branding area.

9. The paint mask assembly as recited in claim 1, wherein the removable mask is sufficiently transparent to allow the mark to be visible through the removable mask when the removable mask is attached to the window.

10. The paint mask assembly as recited in claim 1, wherein the frame and the window comprise a unitary piece of material.

11. The paint mask assembly as recited in claim 1, wherein the removable mask is impervious to paint.

12. A method of using a paint mask assembly, comprising:
receiving a paint mask assembly comprising a frame, a window attached to the frame, and a removable mask attached to and covering at least a portion of the window; and attaching the mask assembly to a surface such that a mark on the surface is visible through a window portion of the mask assembly

13. The method as recited in claim 12, wherein the removable mask is sufficiently transparent so that the mark is visible through the removable mask and the window when the paint mask assembly is attached to the surface.

14. The method as recited in claim 12, further comprising applying paint over the paint mask assembly and removing the removable mask to reveal the mark visible through the window.

15. A method of using a paint mask assembly to protect a fire stamp on a sheet of material, the method comprising:
receiving a sheet of material that is marked with a fire stamp;
receiving a paint mask assembly comprising a frame and a window attached to the frame;
positioning the paint mask assembly over the fire stamp so that the fire stamp is visible through the window; and
attaching the paint mask assembly to the sheet of material.

16. The method as recited in claim 15, wherein the paint mask assembly further comprises a removable mask removably attached to and at least partially covering the window.

17. The method as recited in claim 16, wherein the method further comprises:
applying paint over the paint mask assembly; and
removing the removable mask from the paint mask assembly.

18. The method as recited in claim 15, wherein the frame and the window further comprise a unitary piece of material.

19. The method as recited in claim 15, wherein attaching the paint mask assembly to the sheet of material further comprises applying force to the frame of so that cleats incorporated into the frame are driven into the sheet of material.

20. The method as recited in claim 15, wherein the removable mask is impervious to paint.
